(19) United States
(12) Patent Application Publication
(10) Pub. No.: US 2016/0072086 A1
(43) Pub. Date: Mar. 10, 2016

(54) THIN FILM TRANSISTOR, TRANSISTOR ARRAY, METHOD OF MANUFACTURING THIN FILM TRANSISTOR, AND METHOD OF MANUFACTURING TRANSISTOR ARRAY

(71) Applicants: DIC Corporation, Tokyo (JP); National University Corporation Yamagata University, Yamagata-shi (JP)

(72) Inventors: Tomoko Okamoto, Sakura-shi (JP); Kenichi Yatsugi, Sakura-shi (JP); Yoshinori Katayama, Sakura-shi (JP); Kenjiro Fukuda, Yonezawa-shi (JP); Daisuke Kumaki, Yonezawa-shi (JP); Shizuo Tokito, Yonezawa-shi (JP)

(21) Appl. No.: 14/844,365

(22) Filed: Sep. 3, 2015

(30) Foreign Application Priority Data
Sep. 5, 2014 (JP) 2014-181412

(51) Int. Cl. H01L 51/05; H01L 51/00; H01L 27/28; H01L 51/10

(52) U.S. Cl. CPC H01L 51/0541; H01L 51/105; H01L 51/0022; H01L 27/283

(57) ABSTRACT

Provided is a thin film transistor in which at least a support, source and drain electrodes constituted by a conductor, a semiconductor layer, an insulator layer, and a gate electrode constituted by a conductor are laminated in this order. In a laminated cross section of the thin film transistor, a difference between an electrode width of an electrode on a face coming into contact with the support and an electrode width thereof on a face which is opposite to the face coming into contact with the support and comes into contact with the semiconductor layer falls within a range of ±1 μm. When an arithmetic average roughness in the electrode width of the electrode on the face which is opposite to the face coming into contact with the support and comes into contact with the semiconductor layer is set to Ra, the relation of Ra≦10 nm is satisfied.

### TECHNICAL FIELD

The present invention relates to a thin film transistor, a method of manufacturing the thin film transistor, a transistor array, and a method of manufacturing the transistor array.

Priority is claimed on Japanese Patent Application No. 2014-181412 filed on Sep. 5, 2014, the entire contents thereof being thereby incorporated by reference.

### DESCRIPTION OF RELATED ART

Transistors in which source and drain electrodes, a semiconductor layer, an insulator layer, and a gate electrode constituted by a conductor are laminated have been expected to be utilized for liquid crystal displays, electronic paper, electroluminescence (EL) display devices, RF-ID tags, and the like.

In the transistors used for the above-mentioned purposes, an electrode and a semiconductor layer have been manufactured through a formation step of a dry process such as vapor deposition or sputtering. In recent years, there have been stronger demands for an increase in the density, a reduction in the size, and an improvement in the productivity of a transistor, and thus a method of manufacturing a transistor that does not require a large-scale and expensive vacuum equipment, which is essential for a case in which a vapor deposition method is adopted, has been examined. In recent years, attention has been paid to a wet process such as a printing method capable of suppressing energy consumption due to operation in lowered temperature, increasing productivity, and achieving an increase in density and a reduction in size.

In such a wet process, a method of applying nano-silver ink on a polycarbonate film by spin coating and baking the nano-silver ink to thereby form a gate electrode; forming a gate insulating layer on the gate electrode; forming a streak portion corresponding to a source electrode and a drain electrode by reverse printing of the nano-silver ink on the gate insulating layer, forming the source electrode and the drain electrode by baking the streak portion; and further forming a semiconductor layer on the source electrode and the drain electrode is known as a method of manufacturing a transistor having, for example, a bottom-gate bottom-contact type (BGBC type) structure as illustrated in FIG. 1 (see Patent Literature 1).

However, the transistor having a BGBC type structure obtained by a wet process, disclosed in Patent Literature 1, has problems such as poor charge injection efficiency due to a small contact area between a channel formation portion of a semiconductor and source and drain electrodes, and a large variation in field effect mobility which is an insufficient field effect mobility.

For this reason, various methods of manufacturing a transistor having a staggered structure such as a top gate bottom contact structure (TGBC type) have been examined. A transistor having a top gate type structure is configured such that one face of a source electrode or the like having a predetermined thickness comes into contact with a support and the other face thereof comes into contact with a semiconductor layer. In the transistor, carriers flow through a bulk of an organic semiconductor from the source electrode, flow through an interface between a gate insulating layer provided with a channel formation portion and the semiconductor, and flow through the bulk of the semiconductor to reach a drain electrode. For this reason, a resistance value of the bulk of the semiconductor contributes to a deterioration in transistor characteristics, and the uniformity of a film thickness and crystal of the semiconductor layer are important. When the shape of the source electrode or the like in a thickness direction at an interface coming into contact with the support and the shape thereof at an interface coming into contact with the semiconductor layer are different from each other, the semiconductor layer cannot be formed uniformly, and thus there is a concern of adverse effects being exerted on transistor characteristics. Similarly, when the interface of the source electrode or the like which comes into contact with the semiconductor layer has fine irregularities, stress is applied at the time of laminating each layer in manufacturing the transistor. Thus, a convex portion in the irregularities of the source electrode or the like may partially bite into the semiconductor layer, or may break through the semiconductor layer and reach an insulator layer, which leads to a concern that the transistor does not appropriately operate.

However, in the actual situation, what conditions the source electrode or the drain electrode should satisfy for a cross-sectional structure or an interface state in the transistor has not been sufficiently examined.

### DOCUMENTS OF RELATED ART

### Patent Literature

[Patent Literature 1] WO2010/010791

### SUMMARY OF THE INVENTION

Consequently, a problem that the invention is to solve is to obtain a transistor with a highly reliable top gate bottom contact type structure, not causing the above-mentioned disadvantage, which is cable of exhibiting higher performance than that of a transistor having a bottom gate type structure.

The inventors have found out as a result of wholeheartedly researching to solve such problems that the above-mentioned problem can be solved by controlling a state of an interface where a semiconductor layer comes into contact with cross-sectional shapes of source and drain electrodes to a specific state, and have completed the present invention.

That is, the present invention provides a thin film transistor in which source and drain electrodes, a semiconductor layer, an insulator layer, and a gate electrode constituted by a conductor are laminated in this order. In a laminated cross section of the thin film transistor, a difference between an electrode width of an electrode, having a large electrode width out of the source and drain electrodes, on a face coming into contact with the support and an electrode width thereof on a face which is opposite to the face coming into contact with the support and comes into contact with the semiconductor layer falls within a range of ±1 μm. When an arithmetic surface roughness in the electrode width of the electrode on the face which is opposite to the face coming into contact with the support and comes into contact with the semiconductor layer is set to Ra, a relation of Ra≦10 nm is satisfied.

In addition, the present invention provides a method of manufacturing the thin film transistor, the method including a process of forming a streak portion by performing transfer printing on a support using a member to be transferred which is provided with an ink streak portion for forming source and drain electrodes and has mold releasability, and baking the streak portion, to thereby form the source and drain electrodes. The obtained source and drain electrodes, semiconductor layer, insulator layer, and gate electrode constituted by a conductor are laminated in this order. In a laminated cross section of the obtained thin film transistor, a difference between an electrode width of an electrode, having a large electrode width out of the source and drain electrodes constituted by a conductor, after the baking on a face coming into contact with the support and an electrode width thereof on a face which is opposite to the face coming into contact with the support and comes into contact with the semiconductor layer falls within a range of ±1 μm. When an arithmetic surface roughness in the electrode width of the electrode on the face which is opposite to the face coming into contact with the support and comes into contact with the semiconductor layer is set to Ra, a relation of Ra≦10 nm is satisfied.

According to a thin film transistor of the present invention, when the shape of a source electrode or the like in a thickness direction at an interface coming into contact with a support and the shape thereof at an interface coming into contact with a semiconductor layer are the same as each other and the interface of the source electrode or the like which comes into contact with the semiconductor layer is smooth, a particularly remarkable technical effect that it is possible to configure a highly reliable thin film transistor, having no disadvantage mentioned above, which appropriately operates at all times is exhibited.

In addition, according to the thin film transistor of the present invention, the source electrode or the like is formed by printing, and thus a particularly remarkable technical effect that it is possible to manufacture a highly reliable thin film transistor with high productivity is exhibited.

### BRIEF DESCRIPTION OF THE DRAWINGS

FIG. 1 is a cross-sectional view of a BGBC type transistor.

FIG. 2 is a cross-sectional view of a TGBC type transistor.

FIG. 3 is a diagram illustrating a channel length L and an electrode thickness.

FIG. 4 is a diagram illustrating an electrode width A1 on a face coming into contact with a support, and an electrode width A2 on a face coming into contact with a semiconductor layer.

### DETAILED DESCRIPTION OF THE INVENTION

The present invention relates to a thin film transistor in which at least a support, source and drain electrodes, a semiconductor layer, an insulator layer, and a gate electrode constituted by a conductor are laminated in this order. In a laminated cross section of the thin film transistor, a difference between an electrode width of an electrode, having a large electrode width out of the source and drain electrodes, on a face coming into contact with the support and an electrode width thereof on a face which is opposite to the face coming into contact with the support and comes into contact with the semiconductor layer falls within a range of ±1 μm. When an arithmetic average roughness in the electrode width of the electrode on the face which is opposite to the face coming into contact with the support and comes into contact with the semiconductor layer is set to Ra, the relation of Ra≦10 nm is satisfied.

In the present invention, the thin film transistor refers to a transistor in which source and drain electrodes, a semiconductor layer, an insulator layer, and a gate electrode constituted by a conductor are laminated in this order. In general, the thickness of the thin film transistor which does not include a support is 0.2 μm to 3 μm.

Such a thin film transistor in the present invention can be easily manufactured by laminating source and drain electrodes constituted by a conductor, a semiconductor layer, an insulator layer, and a gate electrode constituted by a conductor in any order so as to exhibit the function of a transistor and to configure the above-mentioned TGBC type laminated structure.

Meanwhile, the present invention has a feature that a state of an interface where a semiconductor layer comes into contact with cross-sectional shapes of source and drain electrodes in a laminated cross section of a thin film transistor is controlled to a specific state.

A support which is applicable to a thin film transistor of the present invention is not limited. For example, it is possible to use a metal thin plate such as stainless steel which is provided with silicon, a thermal silicon oxide film of which the surface is turned into a silicon oxide so as to become an insulating layer, glass, and an insulating layer, plastic films such as polycarbonate (PC), polyethylene terephthalate (PET), polyimide (PI), polyether sulfone (PES), polyethylene naphthalate (PEN), a liquid crystal polymer (LCP), polyparaxylylene, and cellulose; and a composite film obtained by giving a gas barrier layer and a hard coat layer to the plastic films. Among these, from the viewpoint of making a transistor flexible, a plastic film can be preferably used as the support. In addition, the thickness of the support is not limited, but is preferably equal to or less than 150 μm in terms of flexibility and weight reduction.

In a thin film transistor of the present invention, it is possible to adopt any method in order to form source and drain electrodes and to adopt, for example, a dry method such as a vapor deposition method or a wet method such as various types of printing methods. Particularly, it is preferable that a streak portion is formed by performing transfer printing on a support using a member to be transferred, having mold releasability, which is provided with an ink streak portion corresponding to source and drain electrodes constituted by a conductor in that an electrode having high precision and high smoothness is obtained, and is baked, thereby forming the source electrode constituted by a conductor and the drain electrode constituted by a conductor.

Hereinafter, the phrase “member to be transferred, having mold releasability, which is provided with an ink streak portion corresponding to source and drain electrodes constituted by a conductor” may be referred to as the phrase “ink streak portion transfer-forming member”, and the phrase “ink streak portion corresponding to source and drain electrodes” may be referred to as the phrase “electrode forming ink streak portion”.

A method of forming a source electrode and a drain electrode by the above-mentioned transfer printing does not require an expensive vacuum device compared to a method of obtaining a source electrode and a drain electrode by a dry method such as vapor deposition, and can allow the production cost including equipment investment to be drastically reduced. Moreover, in the above-mentioned transfer printing method, it is possible to easily obtaining a high definition electrode having a smaller thickness and a smaller line-and-space (L/S) pitch than in a screen printing method, and to make the source and drain electrodes have a more constant rectangle when seen in a laminated cross section than an ink jet printing method of forming an electrode by making droplets to successively fly. In addition, the temperature of a process can be decreased, and a plastic substrate can be used as a support, and thus it is preferable in terms of realizing essential items in the ubiquitous era, that is, flexibility and low cost.

In a method of manufacturing a thin film transistor in which a source electrode and a drain electrode are formed by a wet method, which is represented by the above-mentioned printing method of the present invention, the streak portion is formed of ink (hereinafter, referred to as “conductive ink”) which forms a conductor by baking. Any ink which is known and in common use can be used as the conductive ink used in the present invention. However, for example, it is possible to use ink in which a conductive material such as conductive metal particles or a conductive polymer is dissolved or dispersed in a solvent (dispersion medium).

As the conductive metal particles, for example, metal particles such as gold, silver, copper, nickel, zinc, aluminum, calcium, magnesium, iron, platinum, palladium, tin, chromium, and lead, and an alloy of the metals such as silver/palladium; thermally decomposable metal compounds, such as a silver oxide, organic silver, organic gold, which are given a conductive metal by thermal decomposition at a relatively low temperature; and conductive metal oxide particles such as a zinc oxide (ZnO) and an indium tin oxide (ITO) can be used.

As the conductive polymer, for example, polyethylene dioxythiophene/polystyrene sulfonic acid (PEDOT/PSS), polyaniline, and the like can be used. Further, a carbon-based conductive material such as carbon nanotube can also be used.

Although a type of solvent (dispersion medium) is not particularly limited, water or an organic solvent capable of dissolving or dispersing a conductive material can be appropriately selected. Specifically, for example, water, various types of organic solvents such as ketone-based, ether-based, and ester-based solvents, and intramolecular hydrogen thereof being partially and entirely fluorinated can be used. Among these, only one type may be used, or two or more types may be used in combination.

Not only the conductive material and the solvent (dispersion medium), but also a binder component such as a resin, an antioxidant, various types of catalysts for promoting film formation, various types of surfactants such as a silicone-based surfactant and a fluorine-based surfactant, a leveling agent, a release accelerator, and the like can be added to the conductive ink when necessary.

The conductive ink can be configured as thermosetting ink by being mixed with a cationically-polymerizable compound such as an oxetane compound, an epoxy compound, or a vinylether compound, or a radically polymerizable compound such as a compound containing a vinyl group or a (meth)acryloyl group, or can be configured as active energy ray-curable ink such as ultraviolet rays or an electron beam. However, such a polymerizable compound may change in volume due to expansion and contraction after polymerization, and thus it is preferable to use a non-polymerizable compound.

As the conductive material, it is possible to form any streak with a smaller line width and to form a conductor by baking at a lower temperature, and thus it is preferable to use conductive material particles of the nm order.

In preparing ink using the conductive metal particles of the nm order, it is preferable to use conductive metal particles, coated with a binder component, which are relatively stable at near room temperature but can form a conductor by baking at a relatively low temperature such as equal to or less than 150° C. The binder component may be a component functioning as a protection material or a dispersing agent for the conductive metal particles. As a material that can be used as such a binder component, a thermoplastic resin having no curability mentioned above is preferably used. For example, the material can include straight chain or branched polyethyleneimine, a polyethyleneimine-polyalkyleneglycol copolymer, an N-oxidized derivative thereof, an N-acetylated derivative thereof, a cationic resin such as polyvinyl-2-pyrrolidone, an anionic resin such as a polyalkyleneglycol mono(meth)acrylate/(meth)acryloyloxyalkyl acid phosphate copolymer, alkanethiols, and alkylamines.

It is preferable to use, for example, conductive ink which is manufactured by treating so that particle sizes are similar or conductive ink obtained by removing coarse particles through centrifugation or filtration in smoothening an interface between a source electrode and a drain electrode on a semiconductor layer side, which is to be described later.

In a method of manufacturing a thin film transistor of the present invention, transfer printing is performed on a support using an ink streak portion transfer-forming member as described above, and a streak portion transferred is baked, and thus it is preferable to use conductive ink suitable for continuously performing this process.

Examples of a method of performing the transfer printing on the support using the ink streak portion transfer-forming member include a gravure offset printing method and a reverse printing method.

The gravure offset printing method is a printing method including a process using a gravure plate provided with a concave portion corresponding to streaks of a source electrode and a drain electrode (having the same pattern as the streak) and a member to be transferred having mold releasability. The method comprises a process of filling the concave portion of the gravure plate with conductive ink, a process of transferring the conductive ink filled in the concave portion to the surface of the member to be transferred having mold releasability to thereby obtain an ink streak portion transfer-forming member, and a process of transferring an ink streak portion moved to the member to be transferred onto a support such as a substrate.

On the other hand, the reverse printing method uses a relief printing plate provided with a convex portion corresponding to reverse patterns of a source electrode and a drain electrode and a member to be transferred having mold releasability. The reverse printing method is a printing method including a process of applying conductive ink onto the entire surface of the member to be transferred, a process of pressing the relief printing plate against the surface of the conductive ink applied onto the member to be transferred to thereby transfer an ink portion corresponding to the reverse patterns of the source and drain electrodes onto the relief printing plate and to remove the ink portion, and a process of performing transfer printing on a support such as a substrate using the member to be transferred provided with an ink streak portion corresponding to the source electrode and the drain electrode by the removal of the reverse patterns pressed by the relief printing plate.

That is, in the present method, a relief printing plate has a convex portion having a reverse pattern of a desired ink streak portion. Thereby, an ink portion corresponding to reverse patterns of a source electrode and a drain electrode is transferred onto the relief printing plate, and thus a streak portion, corresponding to the source electrode and the drain electrode, which has not been pressed by the relief printing plate remains on a member to be transferred. Since the member to be transferred has mold releasability, the member to be transferred, having mold releasability, which is provided with streaks corresponding to the source electrode and the drain electrode is brought into contact with a support such as a substrate, and thus the streak portion is transferred to the support.

As a printing method of forming a streak portion by conductive ink corresponding to a source electrode and a drain electrode in the method of manufacturing a thin film transistor of the present invention, a reverse printing method is more preferable than a gravure offset printing method because an ink streak portion having a smaller line width and a smaller film thickness can be formed.

A streak portion with conductive ink corresponding to a source electrode and a drain electrode forms source and drain electrodes constituted by a conductor, for example, by heating in an oven or baking by irradiation with far-infrared rays. Volatile components contained in the conductive ink are removed from the conductor by the baking. When a binder component is decomposed, the binder component disappears from the inside of the formed conductor. However, when the amount of binder components is extremely smaller than that of conductive materials, the film thickness and shape of the streak portion do not change in the streak portion of the conductive ink before and after the baking and in the streak portion of the conductor obtained after the baking. When a significant reduction in the film thickness of the streak portion and a significant change in the shape thereof are estimated before and after the baking, it is possible to obtain a source electrode and a drain electrode which have an intended film thickness and shape as conductors by forming the ink streak portion so as to have a larger thickness and changing the shape of a plate by estimating these changes.

The thin film transistor of the present invention has the most distinctive feature that an electrode width of at least one electrode having a large electrode width out of source and drain electrodes constituted by a conductor in a laminated cross section on a face coming into contact with a support and an electrode width of the electrode on a face which is opposite to the face coming into contact with the support and comes into contact with a semiconductor layer are the same as or a little different from each other, and that the surface on the face coming into contact with the semiconductor layer is smooth.

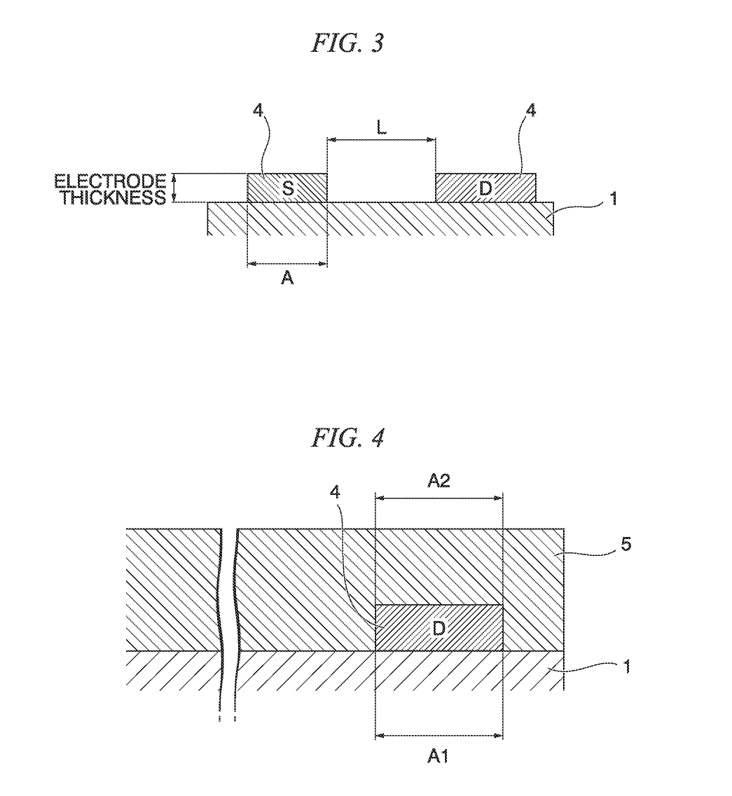

As illustrated in FIG. 2, a TGBC type thin film transistor includes a source electrode 4 and a drain electrode 4 on a support 1. When the electrodes are appropriately formed, a laminated cross section of either of the electrodes also has a quadrangular shape. FIG. 3 illustrates a partial cross-sectional view of a thin film transistor in which an electrode width is sufficiently larger than an electrode thickness and a drain electrode has a larger electrode width than that of a source electrode. At this time, as in FIG. 4, when an electrode width A1 (lower bottom of the above-mentioned quadrangle) of a drain electrode on a face coming into contact with a support and an electrode width A2 (upper bottom thereof) thereof on a face coming into contact with a semiconductor layer are the same as each other and a virtual line (lateral edge of the quadrangle which is equivalent to the thickness of the electrode) which can be drawn from an end of the upper bottom of the quadrangular electrode to an end of the lower bottom is perpendicular to the support, the laminated cross section of the electrode has a rectangular shape. This is an ideal laminated cross section of an electrode. However, the laminated cross section is not likely to have such an ideal shape, and may have a trapezoidal shape in which an upper bottom is shorter than a lower bottom or an inverted trapezoidal shape in which a lower bottom is shorter than an upper bottom.

In other words, in the present invention, that a difference between the electrode width A1 on the face coming into contact with the support and the electrode width A2 on the face coming into contact with the semiconductor layer falls within a range of ±1 μm in the shape of the laminated cross section means that the laminated cross sections of the source and drain electrodes have a rectangular shape or a substantially rectangular shape.

In addition, in the thin film transistor, that the surface on the face coming into contact with the semiconductor layer is smooth is important in exhibiting excellent transistor characteristics. When a description is given using the above-mentioned laminated cross section, the face coming into contact with the semiconductor is equivalent to the upper bottom of the quadrangle. When the upper bottom is disturbed or a projection is present, the electrode cuts into an insulator layer, and thus it is possible to exhibit appropriate transistor characteristics.

In the thin film transistor of the present invention, that the relation of Ra 10 nm is satisfied when an arithmetic average roughness in the electrode width A2 on the face coming into contact with the semiconductor layer is set to Ra means that the surface on the face coming into contact with the semiconductor layer is smooth. The arithmetic average roughness Ra refers to a value, expressed in nanometers (nm), which is obtained by the following specific expression when a portion is cut out from a roughness curve by a reference length in a direction of the average line thereof, an X axis is taken in a direction of the average line of the cut-out portion, a Y axis is taken in a direction of a longitudinal magnification, and the roughness curve is expressed as y=f(χ). The Ra is specified in JIS B 0601 (1994) and JIS B 0031 (1994) in detail. A small letter “l” in the following expression represents the electrode width A2 on the face coming into contact with the semiconductor layer in the present invention.

The arithmetic average roughness can be easily obtained using a device such as an atomic force microscope (commonly referred to as an AFM), for example, Nano Scope IIIa manufactured by Veeco Instruments Inc. with a surface on a side on which the semiconductor layer of the source electrode and the drain electrode is laminated, as a target. When a description is given using, for example, FIG. 2, the arithmetic average roughness can be obtained by setting a range of a 5 μm by 5 μm square so as to straddle any cross section line with the faces of the source and drain electrodes which come into contact with the semiconductor layers from the front direction of the drawing to the depth direction, as targets and by performing measurement in the range. It is possible to obtain the distribution of arithmetic average roughnesses by setting a plurality of ranges of 5 μm by 5 μm squares so as to straddle any cross section line and similarly performing measurement in each of the ranges. When the measurement is performed by setting a plurality of ranges, an average value of the arithmetic average roughnesses measured in the respective ranges can be treated as an arithmetic average roughness in an electrode width.

$$Ra = \frac{1}{𝓁} {\int }_{0}^{𝓁} \vert f ( x ) \vert d x \qquad ( 1 )$$

When source and drain electrodes are obtained, for example, by the above-mentioned reverse printing method, it is preferable to use a member to be transferred having an arithmetic average roughness of a surface on a side having mold releasability being as small as possible, as a member to be transferred having mold releasability. When a reverse printing method is adopted for the formation of the electrodes, an ink streak portion, corresponding to the source and drain electrodes, which comes into contact with a semiconductor layer is provided on the mold-releasable surface of the member to be transferred having mold releasability, the properties of the mold-releasable surface has a significant effect on the properties of the surfaces of the source and drain electrodes which face the semiconductor layer. From such a perspective, in the mold-releasable surface of the member to be transferred having mold releasability, it is preferable to use a member to be transferred having a mold-releasable surface with an arithmetic average roughness of Ra≦510 nm as mentioned above, particularly an arithmetic average roughness of Ra≦10 nm and smaller than that expected for an electrode width, specifically, arithmetic average roughness of Ra=0.5 nm to 2 nm. In addition, the arithmetic average roughness of the surface of the member to be transferred on a side having mold releasability can be measured in the same manner as in the above-mentioned method.

It is preferable in terms of obtaining transistor characteristics that a difference between the electrode width A1 of at least one of the source and drain electrodes on the face coming into contact with the support and the electrode width A2 thereof on the face coming into contact with the semiconductor layer falls within a range of ±1 μm and that the relation of Ra≦10 nm is satisfied when an arithmetic average roughness in the electrode width A2 on the face coming into contact with the semiconductor layer is set to Ra. It is more preferable that the relation of Ra≦5 nm is satisfied, but optimal transistor characteristics are obtained by making both the source and drain electrodes satisfy the above-mentioned requirements.

In addition, as described above, when the source and drain electrodes are obtained, for example, by the above-mentioned reverse printing method, conductive ink is uniformly applied onto the entire of the mold-releasable surface of the member to be transferred having mold releasability so that the same ink film thickness is obtained in any cross section, and a relief printing plate having a highly-precise convex-shaped acute angle portion (edge) is used in order to remove or reduce a difference between the electrode width A1 of the source or drain electrode on the face coming into contact with the support and the electrode width A2 thereof on the face coming into contact with the semiconductor layer, and thus it is possible to make an angle of a portion where the support and the electrode come into contact with each other the same as an angle of a portion where the semiconductor and the electrode come into contact with each other, to make an electrode thickness uniform, and to make the electrode width A1 and the electrode width A2 the same as each other. It is possible to use, for example, a die coater or a slit coater in order to apply the conductive ink so that the ink film thickness becomes uniform, and to use, for example, a glass relief printing plate obtained by dry etching or wet etching of glass in order to obtain a relief printing plate having a highly-precise convex-shaped acute angle portion (edge).

In addition, generally, source and drain electrodes are designed so that electrode widths of both the electrodes become the same. However, in the present invention, when the electrode widths of both the electrodes are different from each other, an electrode width A1 on a face coming into contact with a support and an electrode width A2 thereof on a face coming into contact with a semiconductor layer are measured with any electrode having a larger electrode width.

As illustrated in FIG. 3, a shortest distance between a source electrode and a drain electrode is called a channel length L, and the channel length can be arbitrarily selected from, for example, values of equal to or less than 30 μm in consideration of frequency responsiveness required. In order to obtain an integrated circuit having excellent high-speed responsiveness, and the like, it is preferable to provide a source electrode and a drain electrode so as to have an extremely short channel length such as channel length L≦7 μm, preferably channel length L≦5 μm, and particularly preferably 1 μm to 3 μm.

According to the above-mentioned method of performing transfer printing on a support using an ink streak portion transfer-forming member, by using conductive ink, to thereby form an electrode forming ink streak portion, source and drain electrodes have excellent surface smoothness even when seen not only from a laminated cross section of a thin film transistor after baking but also from the entire interface in the depth direction from the front side of the laminated cross section, and thus the electrode thicknesses thereof become the same, and the formation of the source and drain electrodes having an extremely small film thickness is extremely facilitated.

In addition, according to the above-mentioned method of performing transfer printing on a support using an ink streak portion transfer-forming member to thereby form an electrode forming ink streak portion, adopted electrode widths in a laminated cross section of a thin film transistor are not different from each other, and thus source and drain electrodes having a quadrangular electrode shape, which have no transfer abnormality are obtained in the laminated cross section. The uniformity of a film thickness and crystal of a semiconductor layer located at an upper layer is improved by the provision of the source and drain electrodes, and thus the obtainment of a thin film transistor with smaller variations in field effect mobility and a threshold voltage at the time of being driven as a thin film transistor is facilitated. Thicknesses of the source and drain electrodes for obtaining such a thin film transistor are preferably equal to or less than 100 nm, and are more preferably 30 nm to 80 nm.

Specifically, for example, source and drain electrodes have the same electrode thickness and both have an electrode width which is sufficiently larger than the electrode thickness, and thus the source and drain electrodes, having an appropriately electrode shape which is a rectangular or substantially rectangular shape, which have no abnormality such as concavities or convexities are easily obtained. As a result, it is possible to obtain a transistor which is configured as a thinner film as well as being optimal for obtaining an integrated circuit having excellent high-speed responsiveness, and the like. Such excellent features are features of the above-mentioned transfer printing which cannot be possibly achieved by a printing method of the related art such as a screen printing method or an ink jet printing method. In addition, since much time is required for vacuum vapor deposition in a dry method such as a vapor deposition method, excellent productivity of a thin film transistor manufactured by the manufacturing method of the present invention utilizing transfer printing is more remarkably exhibited.

In addition, a partition wall layer formed so as to surround at least a portion of the source and drain electrodes of the thin film transistor of the present invention is provided on the source and drain electrodes so that a film formation region of a semiconductor layer on a channel is limited, and thus it is possible to suppress a variation in an overlapping width between the semiconductor layer and the source and drain electrodes for each element. In a case of being driven as a thin film transistor by suppressing a variation in an overlapping width, it is possible to obtain a thin film transistor with smaller variations in field effect mobility and a threshold voltage. In particular, when the semiconductor layer is formed by a wet process, there may be a tendency for semiconductor ink to unevenly wet-spread on the source and drain electrodes, and thus it is preferable to provide the partition wall layer in advance before forming the semiconductor layer.

A material used for the above-mentioned partition wall layer is not limited insofar as a material having an insulation property is contained therein. Although an organic or inorganic material which is known and in common use can be used, a liquid repellent material is preferably used because the film formation region of the semiconductor layer is easily controlled at the time of being made to function as a partition wall layer. In addition, any method can be adopted as a method of forming a partition wall layer, a formation method of performing transfer printing of a member to be transferred, having mold releasability, which is provided in an ink streak portion corresponding to the partition wall layer, on a support provided with source and drain electrodes is preferably used in that a high definition partition wall layer is obtained.

The source and drain electrodes of the thin film transistor of the present invention are subjected to surface treatment when necessary, and thus it is possible to improve the efficiency of charge injection into a semiconductor layer. Examples of a material to be used for the surface treatment include a thiol compound such as benzenethiol, chlorobenzene thiol, bromobenzene thiol, fluorobenzenethiol, pentafluorobenzenethiol, pentachlorobenzene thiol, trifluoromethylbenzenethiol, biphenylthiol, fluorenethiol, nitrobenzenethiol, 2-mercapto-5-nitro-benzimidazole, perfluorodecane thiol, 4-trifluoromethyl-2,3,5,6-tetrafluoro thiophenol, 5-chloro-2-mercaptobenzimidazole; a disulphide compound such as diphenyldisulfide; a sulfide compound such as diphenylsulfide; a silane coupling agent such as long-chain fluoroalkylsilane; a metal oxide such as a molybdenum oxide, a vanadium oxide, a tungsten oxide, a rhenium oxide. Particularly, a functional group capable of being chemically coupled to the surface of an electrode is preferably used.

The surface treatment of the source and drain electrodes of the thin film transistor can be performed by either of dry and wet processes which are known and in common use, but a wet process such as a spin coating method, a bar coating method, a slit coating method, a dip coating method, a spray coating method, a dispenser method, or an ink jet method is preferably used in that a drastic reduction in a manufacturing cost can be expected.

It is possible to configure a thin film transistor by laminating a semiconductor layer, an insulator layer, and a gate electrode constituted by a conductor by any method with respect to the source and drain electrodes obtained in the above-mentioned manner so as to exhibit the function of a TGBC type transistor.

An organic or inorganic semiconductor material can be used as a semiconductor material used for a semiconductor layer of a thin film transistor. Examples of the organic semiconductor material to be preferably used include phthalocyanine derivatives, porphyrin derivatives, naphthalene tetracarboxylic acid diimide derivatives, fullerene derivatives, acene compounds such as pentacene and TIPS(triisopropylsilyl)pentacene, various types of pentacene precursors, polyaromatic compounds such as anthracene, perylene, pyrene, phenanthrene, and coronene and derivatives thereof, oligothiophene and a derivative thereof, thiazole derivatives, fullerene derivatives, dinaphthothiophene-based compounds, and carbon-based compounds such as carbon nanotube as low-molecular organic semiconductors, one or more of various types of low-molecular semiconductors obtained by combining thiophene such as benzothienobenzothiophene, phenylene, vinylene, and the like, and copolymers thereof.

In addition, examples of a high molecular compound to be preferably used include polythiophene-based polymers such as polythiophene, poly(3-hexylthiophene) (P3HT), and PQT-12, thiophene-thienothiophene copolymers such as B10TTT, PB12TTT, and PB14TTT, fluorene-based polymers such as F8T2, phenylenevinylene-based polymers such as paraphenylenevinylene, arylamine-based polymers such as polytriarylamine, and the like. In addition to the organic semiconductor materials, a solution soluble Si semiconductor precursor capable of being reformed into an inorganic semiconductor by a heat treatment or energy ray irradiation of an EB or Xe flash lamp, a precursor of an oxide semiconductor such as IGZO, YGZO, or ZnO can be used.

As a semiconductor material used for a semiconductor layer of a thin film transistor, an organic semiconductor is more preferably used than an inorganic semiconductor in that the organic semiconductor allows a semiconductor layer to be easily formed at a lower temperature and is easy to handle. Among organic semiconductors, an organic semiconductor having a high self-aggregating property and being likely to form a crystal structure is preferably used because it can exhibit more excellent transistor characteristics.

In order to form ink using organic and inorganic semiconductor materials, a solvent which can dissolve the semiconductor material at room temperature or by applying some heat, has a moderate volatility, and may be able to form an organic semiconductor thin film after the volatilization of the solvent, is applicable. Examples of the solvent to be used include organic solvents such as toluene, xylene, chloroform, chlorobenzenes, cyclohexylbenzene, tetralin, N-methyl-2-pyrrolidone, dimethylsulfoxide, isophorone, sulfolane, tetrahydrofuran, mesitylene, anisole, naphthalene derivatives, benzonitrile, amylbenzene, γ-butyrolactone, acetone, and methylethylketone.

In addition, it is possible to add a polymer such as polystyrene or poly(methylmethacrylate) and a surface energy adjusting agent such as a silicone-based or fluorine-based surfactant to the solutions for the purpose of improving ink characteristics. In particular, a fluorine-based surfactant added to a crystalline semiconductor solution can be preferably used because it is possible to expect not only an effect of improving ink characteristics but also characteristics of a semiconductor film formed by drying ink, for example, an improvement in the mobility of a thin film transistor.

An insulator material used for an insulator layer of a thin film transistor is not limited insofar as a material having an insulation property is contained therein. Examples of the insulator material include resins for forming an organic film such as a polyparaxylylene resin, a polystyrene resin, a polycarbonate resin, a polyvinyl alcohol resin, a polyvinyl acetate resin, a polysulfone resin, a polyacrylonitrile resin, a methacrylic resin, a polyvinylidene chloride resin, a fluorine-based resin, an epoxy resin, a polyimide resin, a polyamide resin, a polyamide-imide resin, a polyvinylpyrrolidone resin, a polycyanate resin, a polyolefin resin, and a polyterpene resin, or a silane compound, a silazane compound, a magnesium alkoxide compound, an aluminum alkoxide compound, a tantalum alkoxide compound, an ionic liquid, and an ionic gel for forming an inorganic film by hydrolysis and a heat treatment when necessary. Alternatively, one or two or more types thereof may be used in combination, or an oxide such as zirconia, a silicon dioxide, an aluminum oxide, a titanium oxide, or a tantalum oxide, a ferroelectric oxide such as SrTiO₃ or BaTiO₃, a nitride such as a silicon nitride or an aluminum nitride, and dielectric particles such as sulfide or fluoride can be dispersed when necessary.

A solvent applicable to form ink using an insulator material is not limited, and examples of the solvent include various types of organic solvents such as water and hydrocarbon-based, alcohol-based, ketone-based, ether-based, ester-based, glycol ether-based, and fluorine-based solvents. In addition, an antioxidant, a leveling agent, a release accelerator, and various types of catalysts for promoting film formation can be used when necessary.

The semiconductor layer, and an insulator layer and a gate electrode which are to be described later can be formed by either of dry and wet processes which are known and in common use. Specifically, a dry process represented by a vacuum deposition method, a molecular beam epitaxial growth method, an ion cluster beam method, an ion plating method, a sputtering method, an atmospheric pressure plasma method, or a CVD method, or a wet method such as a printing method as exemplified below can be used. In particular, the wet process is a preferable embodiment of the present invention because a drastic reduction in a manufacturing cost can be expected. Examples of the wet process to be used include an inkjet printing method, a screen printing method, a spin coating method, a bar coating method, a slit coating method, a dip coating method, a spray coating method, a gravure printing method, a flexographic printing method, a gravure offset printing method, a relief offset printing method, a reverse printing method, and the like.

When a semiconductor layer is formed by a printing method, semiconductor ink used therefor can be prepared by dissolving or dispersing various types of semiconductor materials, which are known and in common use, in a solvent.

When an insulator layer such as a gate insulating film is formed by a printing method, insulator ink used therefor can be prepared by dissolving or dispersing various types of semiconductor materials, which are known and in common use, in a solvent.

The surface of the insulator layer can be subjected to self-assembled monolayer (SAM) treatment using various types of silane coupling agents such as, for example, hexamethyldisilazane (HMDS), octyltrichlorosilane (OTS-8), octadecyltrichlorosilane, (OTS-18), dodecyltrichlorosilane (DTS), fluorine-substituted octatrichlorosilane (PFOTS), and β-phenethyltrichlorosilane in order to improve transistor characteristics.

In addition, when affinity of an interface between the insulator layer having been subjected to the above-mentioned SAM treatment and the semiconductor layer is insufficient, a fluorine-based surfactant or the like can be used when necessary in order to obtain satisfactory affinity and to improve transistor characteristics.

When a gate electrode is formed by a printing method, any conductive ink, containing the above-mentioned various types of conductive materials, which can be used to form source and drain electrodes can be used as conductive ink used for the gate electrode. Regarding the gate electrode and the source or drain electrode, pieces of conductive ink using different conductive materials can also be used in combination in forming the electrodes. An ink streak portion corresponding to the gate electrode is subjected to baking in the same manner as when the source and drain electrodes are formed, thereby configuring the gate electrode constituted by a conductor.

A thickness of each of the semiconductor layer, the insulating layer, and the gate electrode of the thin film transistor of the present invention are not particularly limited, but the thickness of the semiconductor layer is preferably 20 nm to 100 nm in that more excellent transistor characteristics by reducing a bulk resistance of a semiconductor are obtained. The thickness of the insulating layer is preferably 5 nm to 1500 nm in that it is possible to suppress a variation in an ON/OFF value. The thickness of the gate electrode is preferably 50 nm to 1000 nm in terms of excellent followability to a flexible substrate.

It is possible to form a protective film layer in the uppermost layer of the thin film transistor of the present invention if necessary. It is possible to minimize the influence of open air by providing the protective film layer and to stabilize electrical characteristics of the thin film transistor. As a protective film material used for the protective film layer, a material such as light, oxygen, water, or ions which is capable of forming a film having an excellent barrier property by reforming treatment using heat, light, an electron beam, or the like may be used, and it is possible to use, for example, the same material as the above-mentioned insulator material. When the protective film layer is formed by a wet process, an applicable solvent is not limited, and a material dissolving or dispersing the above-mentioned resin may be used. In addition, various types of silicone-based and fluorine-based surfactants can be added to the protective film material.

The thin film transistor of the present invention can be manufactured by any manufacturing method. For example, source and drain electrodes constituted by a conductor are formed by transferring and printing a member to be transferred, having mold releasability, which is provided with an ink streak portion for forming the source and drain electrodes on a support and by baking the streak portion. Further, all layers for forming the thin film transistor, that is, a semiconductor layer, an insulator layer, and a gate electrode are formed by printing, and thus it is possible to obtain the thin film transistor capable of easily manufacturing an integrated circuit having higher productivity and excellent high-speed responsiveness, and the like. Further, the plurality of thin film transistors each of which is obtained in this manner can be integrated into a transistor array.

### EXAMPLES

### Manufacture of Electrode by Reverse Printing Method

Conductive ink (RAGT-25 manufactured by DIC Corporation, hereinafter, referred to as “nanoparticle silver ink”) having silver particles having an average particle size of the nanometer order being uniformly dispersed in a liquid medium was uniformly applied on a silicone rubber face of a transparent blanket in which a silicone rubber layer is formed on a film, using a slit coater, and was dried to such a degree that tack remains. Thereafter, a glass relief printing plate, obtained by wet etching of glass, which has a highly-precise convex-shaped acute angle portion (edge) was pressed against a surface which was uniformly applied with the nano-particle silver ink to remove an unnecessary portion, in which the glass relief printing plate was provided with a negative pattern which is a desired pattern such as source and drain electrodes or a gate electrode. A pattern remaining on a blanket was lightly pressed against a substrate cut to a predetermined size, and thus a desired pattern was transferred onto the substrate. In addition, when ten ranges of 5 μm by 5 μm squares were provided with the entirety of a silicone rubber face of a transparent blanket as a target and the arithmetic average roughnesses thereof were measured, the average value thereof was 0.8 nm.

Evaluation of Semiconductor Parameter Characteristics

A test element of the following thin film transistor was created, and the characteristics thereof were evaluated. Here, Id-Vg and Id-Vd characteristics were measured using a semiconductor parameter measurement device (4200 manufactured by Keithley instruments Inc.), and field effect mobility and an ON/OFF value were calculated by a well-known method.

### Example 1

A test element of a thin film transistor, illustrated in FIG. 2, which has a TGBC structure was created in the following order and was evaluated.

(1) Formation of source and drain electrodes: a source and drain electrode pattern was formed so as to have a channel length of 5 μm and a channel width of 1000 μm by manufacturing an electrode on alkali-free glass having a thickness of 0.7 mm by the above-mentioned reverse printing method using the above-mentioned nanoparticle silver ink, and was baked in a clean oven at 180° C. for 30 minutes, thereby forming a silver electrode having a thickness of 70 nm.

(2) Surface treatment of an electrode: the above-mentioned source and drain electrode substrate was immersed in an isopropyl alcohol solution containing 30 mmol/L of pentafluorobenzenethiol for 5 minutes, was cleaned using isopropyl alcohol, and was then dried using an air gun.

(3) Formation of a semiconductor layer: 0.5 wt % of polystyrene was added to a mesitylene solution containing 2 wt % of 2,8-difluoro-5,11-bis(triethylsilylethynyl)anthradithiophene as an organic semiconductor, and a semiconductor layer was formed on channels of the source and drain electrodes formed in advance by an ink jet method.

(4) Formation of an insulating layer: polyparaxylilene resin (manufactured by Japan Parylene Co., Ltd., a trade name “parylene-C”) was chemically vapor-deposited using a CVD method on a support having the source and drain electrodes and the semiconductor layer formed thereon, and thereby an insulating layer having a thickness of 1000 nm was formed.

(5) Formation of a gate electrode: a gate electrode pattern was formed on the insulating layer formed in advance by an ink jet printing method using conductive silver ink for an ink jet, and was baked on a hot plate at 120° C. for 30 minutes, and thereby a silver electrode having a thickness of 150 nm was formed.

### Comparative Example 1

A test element of a thin film transistor was created and evaluated by the same method as that in Example 1 except that a method of forming source and drain electrodes was changed as follows.

Formation of source and drain electrodes: there was an attempt to perform the screen printing of an ink pixel portion equivalent to a source and drain electrode pattern on alkali-free glass having a thickness of 0.7 mm using conductive silver ink for screen printing so as to have an electrode width of 50 μm, a channel length of 5 μm, and a channel width of 1000 μm. However, a short circuit occurred between the source electrode and the drain electrode, and disconnection was observed in the electrode. For this reason, an ink pixel portion equivalent to a source and drain electrodes pattern was formed by making a modification so as to have an electrode width of 70 μm, a channel length of 50 μm, and a channel width of 1000 μm on a face coming into contact with a support, and was baked in a clean oven at 180° C. for 30 minutes, thereby forming a silver electrode having a thickness of 5 μm.

### Comparative Example 2

A test element of a thin film transistor was created and evaluated by the same method as that in Example 1 except that a method of forming source and drain electrodes was changed as follows.

Formation of source and drain electrodes: there was an attempt to perform the ink jet printing of an ink pixel portion equivalent to a source and drain electrode pattern on alkali-free glass having a thickness of 0.7 mm using conductive silver ink for ink jet so as to have an electrode width of 50 μm, a channel length of 5 μm, and a channel width of 1000 μm. However, a short circuit occurred between the source electrode and the drain electrode, and disconnection was observed in the electrode. For this reason, an ink pixel portion equivalent to a source and drain electrodes pattern was formed by making a modification so as to have an electrode width of 100 μm, a channel length of 100 μm, and a channel width of 1000 μm on a face coming into contact with a support, and was baked in a clean oven at 120° C. for 30 minutes, thereby forming a silver electrode having a thickness of 150 nm.

### Comparative Example 3

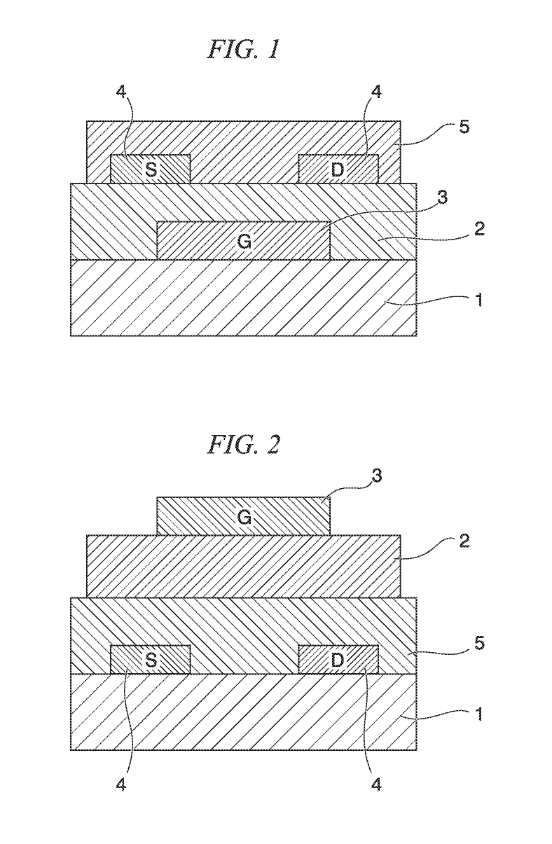

A test element of a thin film transistor, illustrated in FIG. 1, which has a BGBC structure was created in the following order and was evaluated.

(1) Formation of a gate electrode: a gate electrode pattern was formed by manufacturing an electrode on alkali-free glass having a thickness of 0.7 mm by a reverse printing method using the above-mentioned nanoparticle silver ink, and was baked in a clean oven at 180° C. for 30 minutes, thereby forming a silver electrode having a thickness of 150 nm.

(2) Formation of an insulating layer: polyparaxylilene resin (manufactured by Japan Parylene Co., Ltd., a trade name “parylene-C”) was chemically vapor-deposited using a CVD method on a support having the source and drain electrodes and the semiconductor layer formed thereon, and thereby an insulating layer having a thickness of 500 nm was formed.

(3) Formation of source and drain electrodes: an ink pixel portion equivalent to a source and drain electrode pattern was formed so as to have a channel length of 5 μm and a channel width of 1000 μm by manufacturing an electrode by a reverse printing method using the above-mentioned nanoparticle silver ink, and was baked in a clean oven at 180° C. for 30 minutes, and thereby a silver electrode having a thickness of 70 nm was formed.

(4) Surface treatment of an electrode: the above-mentioned source and drain electrode substrate was immersed in an isopropyl alcohol solution containing 30 mmol/L of pentafluorobenzenethiol for 5 minutes, was cleaned using isopropyl alcohol, and was then dried using an air gun.

(5) Formation of a semiconductor layer: 0.5 wt % of polystyrene was added to a mesitylene solution containing 2 wt % of 2,8-difluoro-5,11-bis(triethylsilylethynyl)anthradithiophene as an organic semiconductor, and a semiconductor layer was formed on channels of the source and drain electrodes formed in advance by an ink jet printing method.

### Example 2

A test element of a thin film transistor was created and evaluated by the same method as that in Example 1 except that a method of forming an insulating layer was changed as follows.

Formation of an insulating layer: a fluororesin solution (manufactured by Asahi Glass Co., Ltd. a trade name “CYTOP”) was deposited by a spin coating method and was baked on a hot plate at 50° C. for one hour, thereby forming an insulating layer having a thickness of 800 nm.

An electrode width A1 on a face coming into contact with a support, an electrode width A2 on a face coming into contact with a semiconductor layer, A1-A2, an arithmetic average roughness Ra in the electrode width A2 on the face coming into contact with the semiconductor layer, and obtained transistor characteristics which were measured in source and drain electrodes are shown in Table 1.

In addition, the electrode widths A1 and A2 and the arithmetic average roughness Ra were measured after forming a silver electrode and performing surface treatment with respect to each of the source and drain electrodes and before forming a semiconductor layer located at upper side.

The electrode widths A1 and A2 were measured for any five cross sections in the depth direction from the front direction in the cross-sectional view of FIG. 2, the arithmetic average roughness Ra was measured for five ranges of 5 μm by 5 μm squares which are set to straddle the five cross sections, and maximum values among the measured values were set to A1, A2, and Ra.

When there is an attempt to obtain source and drain electrodes by a screen printing method or an ink jet printing method, it can be understood that not only the electrode width A1 on the face coming into contact with the support and the electrode width A2 on the face coming into contact with the semiconductor layer are considerably different from each other, but also the arithmetic average roughness Ra is large, which results in a deterioration in the smoothness of the electrode surface on the face coming into contact with the semiconductor layer.

TABLE 1

| | | Compar- | Compar- | Compar- | |
|---|---|---|---|---|---|
| | Example | ative | ative | ative | Example |
| | 1 | Example 1 | Example 2 | Example 3 | 2 |
| A1 (μm) | 50 | 70 | 110 | 50 | 50 |
| A2 (μm) | 49.6 | 35 | 90 | 49.5 | 49.6 |
| Difference | 0.4 | 35 | 20 | 0.5 | 0.4 |
| between A1 | | | | | |
| and A2; | | | | | |
| A1-A2 | | | | | |
| (μm) | | | | | |
| Ra (nm) | 3.5 | 1500 | 550 | 4.0 | 3.5 |
| field effect | 0.4 | No | 0.05 | 0.02 | 0.3 |
| mobility | | character- | | | |
| (cm²/Vs) | | istic | | | |
| ON/OFF | 1 × 10⁶ | <10 | 1 × 10² | 5 × 10⁶ | 3 × 10⁶ |
| value | | | | | |

As seen from comparison between Example 1 and Comparative Examples 1 and 2, when a reverse printing method is devised and adopted, it is obvious that the electrode width A1 on the face coming into contact with the support and the electrode width A2 on the face coming into contact with the semiconductor layer are substantially the same as each other even when any laminated cross section is selected, that a TGBC type thin film transistor having a small arithmetic average roughness Ra of the electrode surface on the face coming into the semiconductor layer is obtained even when any range of the electrode surface set to straddle the laminated cross section is selected, and that the thin film transistor exhibits excellent field effect mobility.

According to the thin film transistor of the present invention, laminated cross sections of source and drain electrodes have a rectangular shape or a substantially rectangular shape, and an interface on the side with the electrodes and a semiconductor layer laminated on each other has excellent surface smoothness, and thus it is possible to provide the transistor, having a highly reliable top gate type structure, which is capable of exhibiting higher performance than that of a transistor having a bottom gate type structure and does not cause the above-mentioned disadvantage.

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

### EXPLANATION OF REFERENCES

1: SUBSTRATE
2: INSULATOR LAYER
3, G: GATE ELECTRODE
4: SOURCE ELECTRODE AND DRAIN ELECTRODE
5: SEMICONDUCTOR LAYER
S: SOURCE ELECTRODE
D: DRAIN ELECTRODE
A, A1, A2: ELECTRODE WIDTH
L: CHANNEL WIDTH

What is claimed is:

1. A thin film transistor in which at least a support, source and drain electrodes constituted by a conductor, a semiconductor layer, an insulator layer, and a gate electrode constituted by a conductor are laminated in this order,
wherein in a laminated cross section of the thin film transistor, a difference between an electrode width of an electrode, having a large electrode width out of the source and drain electrodes, on a face coming into contact with the support and an electrode width thereof on a face which is opposite to the face coming into contact with the support and comes into contact with the semiconductor layer falls within a range of ±1 μm, and
wherein when an arithmetic average roughness in the electrode width of the electrode on the face which is opposite to the face coming into contact with the support and comes into contact with the semiconductor layer is set to Ra, a relation of Ra≦10 nm is satisfied.

2. The thin film transistor according to claim 1, wherein electrode thicknesses of the source and drain electrodes in the laminated cross section of the thin film transistor are the same as each other, and both the electrode thicknesses of the source and drain electrodes are equal to or less than 100 nm.

3. The thin film transistor according to claim 1, wherein when a channel length between the source electrode and the drain electrode is set to L, a relation of L≦7 μm is satisfied.

4. The thin film transistor according to claim 1, wherein the semiconductor layer is constituted by an organic semiconductor.

5. A transistor array obtained by integrating a plurality of the thin film transistors according to claim 1.

6. A method of manufacturing the thin film transistor according to claim 1, the method comprising a process of forming a streak portion by performing transfer printing on a support using a member to be transferred which is provided with an ink streak portion for forming source and drain electrodes and has mold releasability, and baking the streak portion, to thereby form the source electrode constituted by a conductor and the drain electrode constituted by a conductor,
wherein the obtained source and drain electrodes, semiconductor layer, insulator layer, and gate electrode constituted by a conductor are laminated in this order.

7. A method of manufacturing a transistor array, the method comprising:
a process of manufacturing the thin film transistor according to claim 6; and
a process of integrating a plurality of the thin film transistors obtained.
